(19) United States
(12) Patent Application Publication
(10) Pub. No.: US 2016/0249482 A1
(43) Pub. Date: Aug. 25, 2016

(54) STRUCTURE FOR CURVED DISPLAY DEVICE AND METHOD OF MANUFACTURING FRAME FOR CURVED DISPLAY DEVICE USING THE SAME

(71) Applicant: SAMSUNG DISPLAY CO., LTD., Yongin-si (KR)

(72) Inventors: Jae Sang LEE, Asan-si (KR); So Jeong LA, Suwon-si (KR); Su Chang RYU, Yongin-si (KR); Lu Ly LEE, Yongin-si (KR)

(21) Appl. No.: 14/918,343

(22) Filed: Oct. 20, 2015

(30) Foreign Application Priority Data
Feb. 25, 2015 (KR) 10-2015-0026804

(51) Int. Cl. H05K 7/18

(52) U.S. Cl. CPC H05K 7/186

(57) ABSTRACT

Disclosed herein is a structure for a curved display device. The structure for a curved display device includes: a plurality of unit body parts each comprising a sheet bent into an arcuate shape; and at least one bent part through which adjacent ones of the unit body parts are connected.

### CROSS-REFERENCE TO RELATED APPLICATION

This application claims priority to, and the benefit of, Korean Patent Application No. 10-2015-0026804 filed in the Korean Intellectual Property Office on Feb. 25, 2015, the entire contents of which are incorporated herein by reference.

### BACKGROUND

(a) Field

The present invention relates to a structure for a curved display device and a method of manufacturing a frame for a curved display device using the same.

(b) Description of the Related Art

In accordance with the demand of consumers for larger screens, the size of image display devices such as televisions (TVs) has gradually increased with time. However, as screen sizes grow, the distance from the eyes of the viewer to both end portions of the image display device becomes significantly larger than a distance from the eyes of the viewer to a central portion of the image display device. This difference reduces the viewer's sense of immersion.

In order to solve this problem, a method of improving immersion by forming the image display device in a curved shape has been used. In order to manufacture the curved image display device, a method of compressing and manufacturing a frame, which is a body, using press equipment is generally used. A length at which two molds closely adhering to the frame at upper and lower sides, respectively, in the press equipment are vertically maximally spaced apart from each other is called a stroke length.

However, in the case of image display devices having large screens, a very large space is required in a press process due to the size of the frame and the amount by which it must be bent. This requires press equipment with larger and larger stroke lengths. However, this results in increased manufacturing cost. In addition, the resulting increased movement length of the mold in the press equipment also results in increased process time.

The above information disclosed in this Background section is only for enhancement of understanding of the background of the invention and therefore it may contain information that does not form the prior art that is already known in this country to a person of ordinary skill in the art.

### SUMMARY

Embodiments of the present invention provide a structure for a curved display device and a method of manufacturing a frame for a curved display device using the same. Embodiments of the invention provide the advantages of manufacturing a component for a large-screen curved display device without need for separate press equipment.

An exemplary embodiment of the present invention provides a structure for a curved display device, that includes: a plurality of unit body parts each comprising a sheet bent into an arcuate shape; and at least one bent part through which adjacent ones of the unit body parts are connected.

The unit body parts may include: base parts connected to each other through respective ones of the at least one bent part; and at least one extension part extending from the corresponding base part.

The unit body parts may each have the same radius of curvature.

The unit body parts may have different radii of curvature.

The at least one bent part may comprise more than one bent part, and the bent parts may be formed at predetermined intervals.

Another exemplary embodiment of the present invention provides a method of manufacturing a frame for a curved display device, the method including: receiving a structure for a curved display device, the structure comprising a plurality of unit body parts, and at least one bent part through which adjacent ones of the unit body parts are connected; bending the unit body parts so that each unit body part has an arcuate shape; and bonding two adjacent unit body parts to each other.

In the structure for a curved display device according to an exemplary embodiment of the present invention, the unit body parts are connected to each other by the bent part. Therefore, when there is a space corresponding to a height occupied by one unit body part, the structure for a curved display device may be easily manufactured using the press equipment.

More specifically, since the structure for a curved display device may be manufactured without increasing a stroke length of the press equipment, a press equipment having a significantly large stroke length does not need to be separately prepared. Therefore, manufacturing cost may be decreased. Also, in the case of manufacturing the structure for a curved display device according to an exemplary embodiment of the present invention, the number of unit body parts is increased to decrease a height occupied by the unit body parts, such that a movement length of a mold in the press equipment may be further decreased as compared with the related art. Therefore, a tack time is decreased, thereby making it possible to significantly increase productivity.

### BRIEF DESCRIPTION OF THE DRAWINGS

FIG. 1 is a perspective view illustrating a structure for a curved display device according to an exemplary embodiment of the present invention.

FIG. 2A is a front view and a plan view illustrating the structure of FIG. 1.

FIG. 2B is a front view and a plan view illustrating a structure for a curved display device according to another exemplary embodiment of the present invention.

FIG. 2C is a front view and a plan view illustrating a structure for a curved display device according to yet another exemplary embodiment of the present invention.

FIG. 3 is a view illustrating a process of manufacturing a structure for a curved display device according to an exemplary embodiment of the present invention using a press.

FIG. 4 is a flow chart illustrating a method of manufacturing a frame for a curved display device according to an exemplary embodiment of the present invention.

FIGS. 5A to 5C are views illustrating various methods of bonding extension parts to each other.

FIG. 5A is a view illustrating a state of bonding the extension parts to each other by a method by welding.

FIG. 5B is a view illustrating a process of bonding the extension parts to each other.

FIG. 5C is a view illustrating another process of bonding the extension parts to each other.

FIG. 6 is a perspective view illustrating a frame along with the curved display device structure of FIG. 1.

### DETAILED DESCRIPTION OF THE EMBODIMENTS

Hereinafter, exemplary embodiments of the present invention will be described in detail with reference to the accompanying drawings so that those skilled in the art to which the present invention pertains may easily practice the present invention. However, the present invention may be implemented in various different forms and is not limited to exemplary embodiments provided herein.

Portions unrelated to the description will be omitted in order to obviously describe the present invention, and similar components will be denoted by the same reference numerals throughout the present specification.

In addition, in several exemplary embodiments, components having the same configuration will be representatively described using the same reference numerals in an exemplary embodiment, and only components different from those of an exemplary embodiment will be described in the other exemplary embodiments.

Throughout the present specification, when any one part is referred to as being “connected to” another part, it means that any one part and another part are “directly connected to” each other or are “indirectly connected to” each other with the other part interposed therebetween. In addition, throughout the present specification, unless explicitly described to the contrary, the word “comprise” and variations such as “comprises” or “comprising”, will be understood to imply the inclusion of stated elements but not the exclusion of any other elements.

The various Figures are not necessarily to scale. All numerical values are approximate, and may vary. All examples of specific materials and compositions are to be taken as nonlimiting and exemplary only. Other suitable materials and compositions may be used instead.

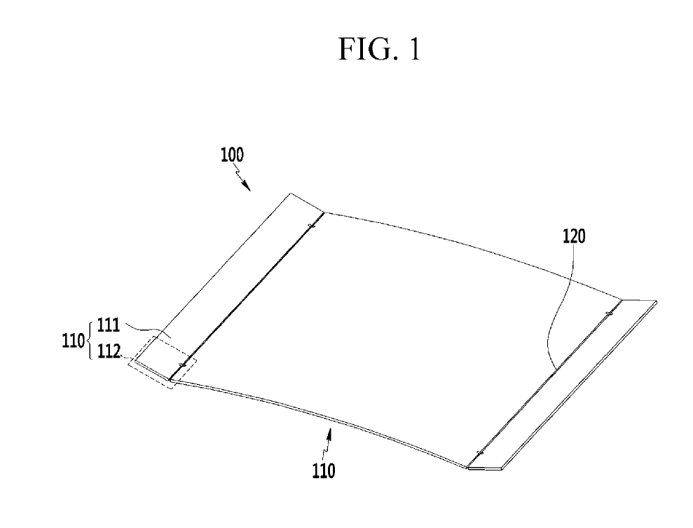

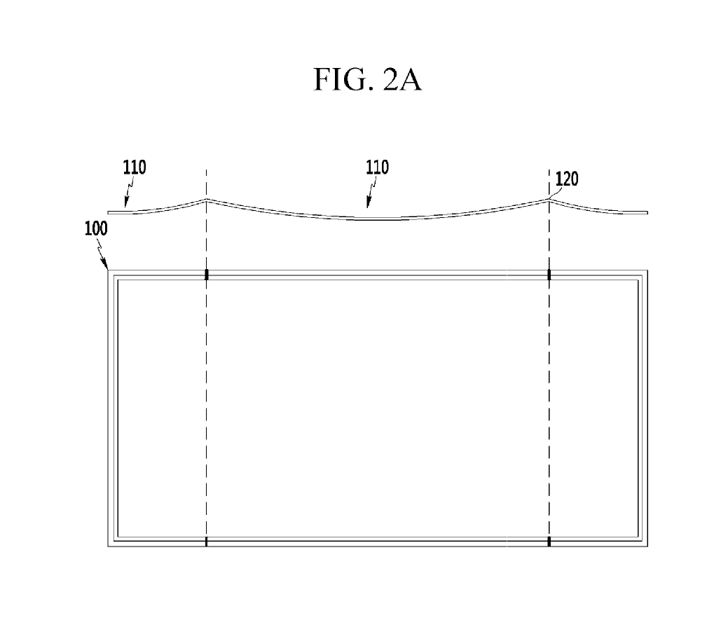

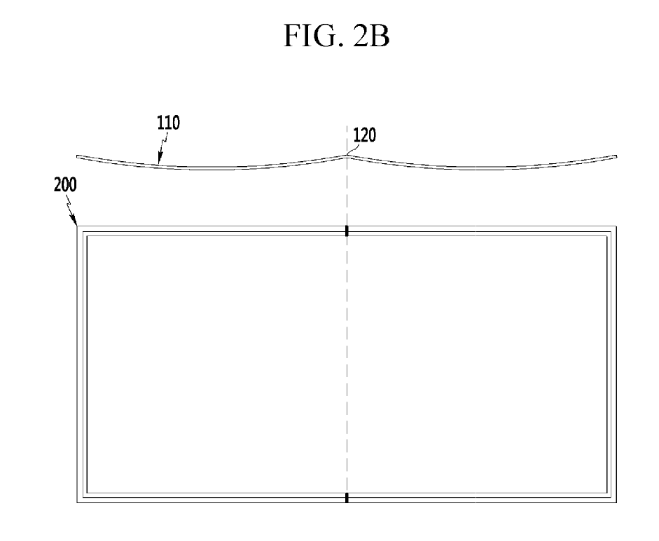

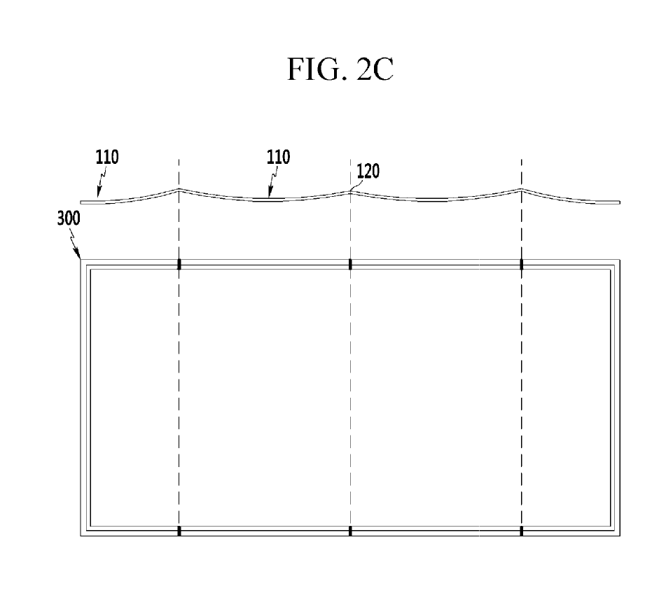

FIG. 1 is a perspective view illustrating a structure for a curved display device according to an exemplary embodiment of the present invention, and FIG. 2A is a front view and a plan view illustrating the structure of FIG. 1.

Referring to FIGS. 1 and 2A, the structure 100 for a curved display device according to an exemplary embodiment of the present invention is configured to include a plurality of unit body parts 110 and at least one bent part 120.

The unit body part 110 has an arc shaped cross section and a thin sheet-like shape. In the structure 100 for a curved display device according to an exemplary embodiment of the present invention, multiple unit body parts 110 are connected in parallel with each other. Sizes of the unit body parts 110 may be different from each other.

For example, in the case in which the structure 100 for a curved display device according to an exemplary embodiment of the present invention is configured of three unit body parts 110 as illustrated in FIG. 1, a size of a central unit body part 110 may be larger than those of unit body parts 110 positioned at both sides thereof. The sizes of any of these unit body parts 110 may vary. For example, although not illustrated in the accompanying drawings, sizes of the respective unit body parts 110 may be the same as each other.

The bent parts 120 allow the unit body parts 110 to be connected to each other in a bent state. Although the bent part 120 may be manufactured separately from the unit body part 110 and may be coupled to the unit body part 110, it may be advantageous in terms of convenience of manufacturing to manufacture the bent part 120 and the unit body part 110 integrally with each other. The bent parts 120 may be bent at a specific angle, which may be any desired angle and which may vary as desired.

Meanwhile, a unit body 110 may include, for example, a base part 111 and at least one extension part 112.

The base parts 111 have ends connected to each other via the bent part 120. The base part 111 may have, for example, a rectangular shape or a square shape.

The extension part 112 is located at an end of the base part 111. The extension parts 112 may be formed at a side perpendicular to a side at which the base parts 111 are connected to each other. That is, in the case in which left and the right sides of the base parts 111 are coupled to each other, the extension parts 112 may be formed at upper sides or lower sides of the base parts 111. The extension parts 112 may be formed at only the upper sides of the base parts 111, only the lower side of the base parts 111, or at both upper and lower sides thereof.

The extension part 112 may be made of the same material as that of the base part 111. A thickness of the extension part 112 may be the same as that of the base part 111. The extension part 112 may be formed integrally with the base part 111 in a manufacturing process.

Meanwhile, the plurality of unit body parts 110 may have the same radius of curvature. Alternatively, the plurality of unit body parts 110 may have different radii of curvature. That is, since the respective radii of curvature of the unit body parts 111 may vary from manufacturer to manufacturer, the radii of curvature of the unit body parts 110 are not limited to any specific values.

The number of bent parts 120 may be plural, and the bent parts 120 may be formed at predetermined intervals.

FIG. 2B is a front view and a plan view illustrating a structure for a curved display device according to another exemplary embodiment of the present invention.

As illustrated in FIG. 2B, in the case in which the structure 100 for a curved display device according to an exemplary embodiment of the present invention is configured of two unit body parts 110, only one bent part 120 is present.

FIG. 2C is a front view and a plan view illustrating a structure for a curved display device according to yet another exemplary embodiment of the present invention.

As illustrated in FIG. 2C, in the case in which the structure 100 for a curved display device according to an exemplary embodiment of the present invention is configured of four unit body parts 110, the number of bent parts 120 may be three, and the bent parts 120 may be spaced apart from each other by a predetermined distance. Any distance or distances may be employed.

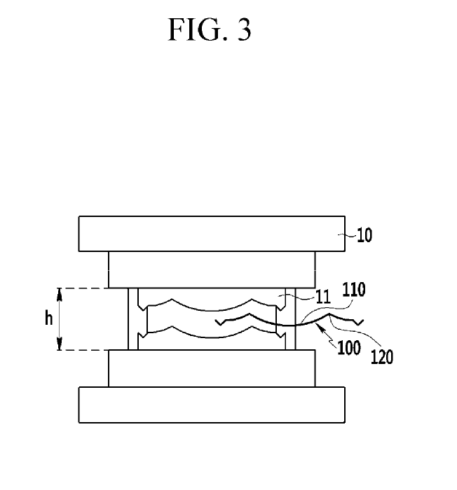

FIG. 3 is a view illustrating a process of manufacturing a structure for a curved display device according to an exemplary embodiment of the present invention using press equipment.

In the structure 100 for a curved display device according to an exemplary embodiment of the present invention having the above-mentioned structure, the unit body parts 110 are connected to each other in parallel by the bent parts 120. Therefore, when the press has at least an amount of space corresponding to a height occupied by one unit body part 110, the structure 100 for a curved display device may be readily manufactured using the press equipment.

Thus, since the structure 100 for a curved display device may be manufactured without increasing a stroke length h of the press equipment 10, custom press equipment having a significantly larger stroke length does not need to be separately prepared. Therefore, a manufacturing cost may be decreased.

Rather, in the case of manufacturing the structure 100 for a curved display device according to an exemplary embodiment of the present invention, the number of unit body parts 110 is increased to decrease a height occupied by the unit body parts 110, such that a movement length h of a mold 11 in the press equipment 10 may be further decreased as compared with the related art. Therefore, a tack time is decreased, or process time is reduced, thereby making it possible to significantly increase productivity.

Next, a method of manufacturing a frame for a curved display device using the structure for a curved display device having the above-mentioned structure will be described with reference to the accompanying drawings.

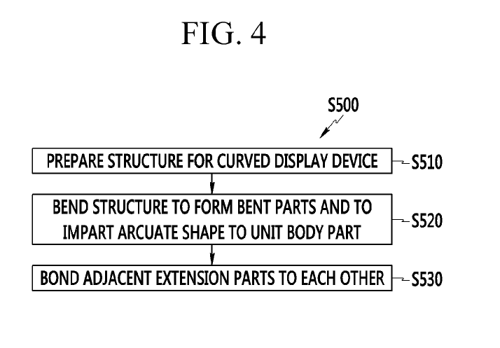

FIG. 4 is a flow chart illustrating a method of manufacturing a frame for a curved display device according to an exemplary embodiment of the present invention.

Referring to FIG. 4, the method (S500) of manufacturing a frame for a curved display device according to an exemplary embodiment of the present invention includes preparing the structure for a curved display device described above (S510), bend structure to form bent parts and to impart arcuate shape to unit body part (S520), and bonding two adjacent extension parts to each other (S530).

In (S510), the structure for a curved display device configured of the unit body parts and the bent parts is prepared. The number of unit body parts configuring the structure for a curved display device may be freely changed depending on a design.

In (S520), a general method of bending a plate shaped, or sheet-like, object using a separate jig or tool may be used. Such methods are known. Therefore, a detailed description for this will be omitted.

In (S530), the two adjacent extension parts are bonded to each other so as not to be separated from each other.

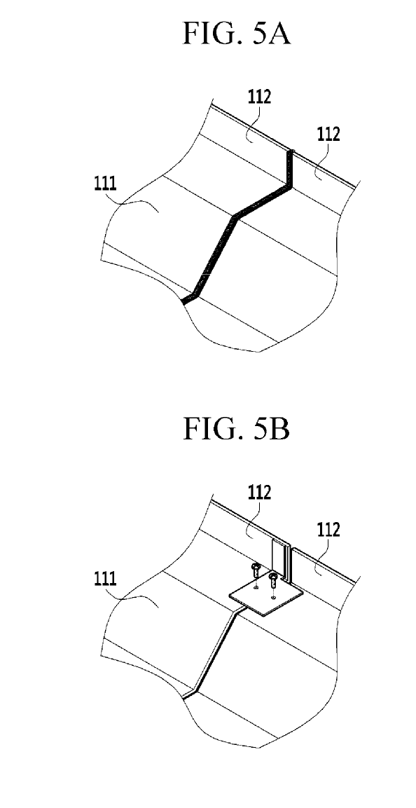

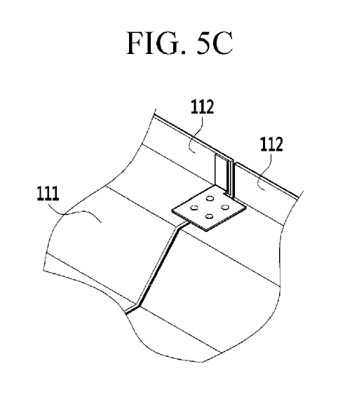

FIGS. 5A to 5C are views illustrating various methods of bonding extension parts to each other.

FIG. 5A is a view illustrating the bonding of extension parts to each other by a method y welding, FIG. 5B is a view illustrating the attaching of extension parts to each other by bolt, and FIG. 5C is a view illustrating the bonding of extension parts to each other by a fixing pin. As illustrated in FIGS. 5A to 5C, any methods used to bond parallel metal plates to each other may be used to bond the extension parts 112. Therefore, a method of bonding the extension parts 112 to each other is not limited to the specific methods shown, and any other method is contemplated as well.

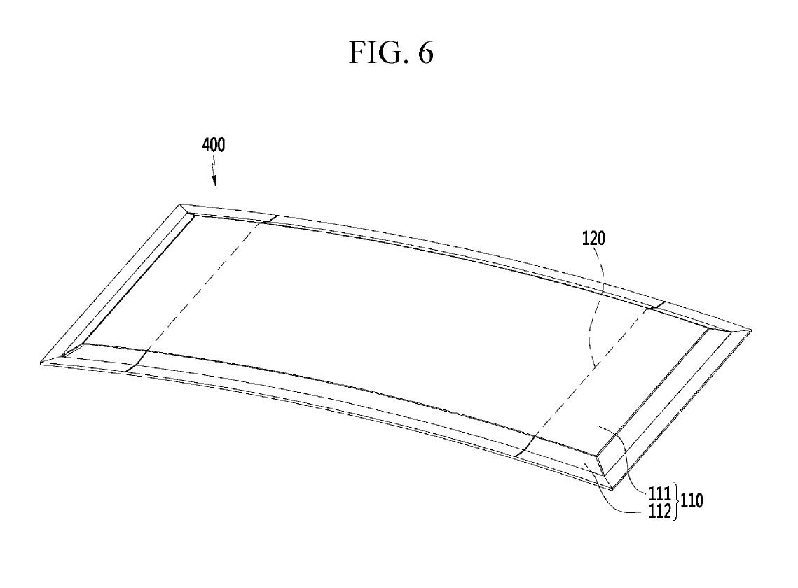

FIG. 6 is a perspective view illustrating a frame along with the curved display device structure of FIG. 1.

As illustrated in FIG. 6, the frame 400 may have an arcuate shape. The frame 400 may be used as a main frame in which various components are mounted in a curved television (TV).

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims. Therefore, it will be understood by those skilled in the art that various modifications and other equivalent exemplary embodiments may be made from the present invention. Therefore, an actual technical protection scope of the present invention is to be defined by the claims. Furthermore, different features of the various embodiments, disclosed or otherwise understood, can be mixed and matched in any manner to produce further embodiments within the scope of the invention.

### DESCRIPTION OF SYMBOLS

100, 200, 300: structure for curved display device

400: frame for curved display device

110: unit body part

111: base part

112: extension part

120: bent part

What is claimed is:

1. A structure for a curved display device, comprising:
a plurality of unit body parts each comprising a sheet bent into an arcuate shape; and
at least one bent part through which adjacent ones of the unit body parts are connected in a bent state.

2. The structure for a curved display device of claim 1, wherein:
the unit body parts include:
base parts connected to each other through respective ones of the at least one bent part; and
at least one extension part extending from the corresponding base part.

3. The structure for a curved display device of claim 2, wherein:
the unit body parts each have the same radius of curvature.

4. The structure for a curved display device of claim 2, wherein:
the unit body parts have different radii of curvature.

5. The structure for a curved display device of claim 1, wherein:
the at least one bent part comprises more than one bent part, and
the bent parts are formed at predetermined intervals.

6. A method of manufacturing a frame for a curved display device, the method comprising:
receiving a structure for a curved display device, the structure comprising a plurality of unit body parts, and at least one bent part through which adjacent ones of the unit body parts are connected;
bending the unit body parts so that each unit body part has an arcuate shape; and
bonding two adjacent unit body parts to each other.

7. The method of claim 6, wherein the unit body parts include:
base parts connected to each other through the bent part; and
at least one extension part extending from the corresponding base part.

8. The method of claim 7, wherein the unit body parts each have the same radius of curvature.

9. The method of claim 7, wherein the unit body parts have different radii of curvature.

10. The method of claim 6, wherein the at least one bent part comprises more than one bent part, and the bent parts are formed at predetermined intervals.
